(19) United States
(12) Patent Application Publication
(10) Pub. No.: US 2017/0176061 A1
(43) Pub. Date: Jun. 22, 2017

(54) PORTABLE COOLING UNIT

(71) Applicant: Paradox Thermal, LLC, Pittsburgh, PA (US)

(72) Inventor: Thomas Andrew Moran, Pittsburgh, PA (US)

(21) Appl. No.: 15/381,850

(22) Filed: Dec. 16, 2016

Related U.S. Application Data
(60) Provisional application No. 62/268,554, filed on Dec. 17, 2015.

(51) Int. Cl. F25B 21/02; H01L 35/30; F25B 27/00; H02S 10/40

(52) U.S. Cl. CPC F25B 21/02; H02S 10/40; H01L 35/30; F25B 27/002; F25B 2321/0251; F25B 2321/021

(57) ABSTRACT

Disclosed herein is a powered air cooling device contained within a single portable unit and a method of using said device. The portable solar powered cooling unit can include some or all of the following: solar panels, a rechargeable power source, a thermostat unit, a thermoelectric (TE) cooling unit, a heat dissipation unit, a cooling unit resembling a heat sink or an actual heat sink, an air distribution device, for example in one preferred embodiment, a low power high volume fan, and a structure that directs air intake and outflow. The unit features the ability to maintain a stable ambient air temperature via heating, cooling, humidity control, or all of the above. The unit may also feature a form factor which allows the dissipation of the desired cooling or heating to occur at a faster rate. The unit itself although portable, may be fixed in place for more permanent applications. The unit can be used to provide temperature and humidity control.

### CROSS-REFERENCE TO RELATED APPLICATION

This application claims the benefit under 35 U.S.C. 119 §(e) of the earlier filing date of U.S. Provisional Patent Application No. 62/268,554, filed on Dec. 17, 2015, the entire contents of which are incorporated herein by reference.

### BACKGROUND

The present disclosure relates to an apparatus and method of cooling a designated area, using a mobile power source, such as solar panels. This device provides a net zero cooling solution that can be used in many applications including by way of example parked vehicles, tents, living spaces, and military operations, where there is no readily available electric power source. In one preferred embodiment, the present invention uses the novel combination of a thermoelectric cooler and solar panels. Other comparable products are not as compact as the disclosed portable cooling unit. Common products that attempt to solve the same problems as this invention are air exchangers, which have limited effectiveness. In one embodiment, the disclosed invention is a high quality solution that is smaller, more effective, and utilizes a renewable energy source. In other embodiments, the disclosed invention is also scalable. It may be larger or smaller and built to suit the intended application making it incredibly versatile. The smaller scale units may be used in the cabin of a vehicle, whereas the solar panel can be placed inside or outside and connected via wires to the rest of the device. Hoses, ducts, piping, or other similar conduits may be utilized to direct the flow of cold air, and likewise exhaust the heat generated. Likewise, using hoses, pipes or ducts, the unit may be placed in an optimal location, with the cold air traveling wherever is desired.

Disclosed herein is a portable unit which in one preferred embodiment provides air cooling powered by a power source that can be charged by solar power. Operation of one preferred embodiment of the unit is based upon the ability of solar panels to charge a power bank such as a rechargeable battery, which will allocate power to a Peltier (thermoelectric) unit and fan to disperse cooled air. The design of the unit can be optimized for the cabin of a vehicle or the interior of the structure in which it is used. Heat generated from the Peltier unit can be contained or exhausted, lowering the net temperature of the cabin or interior. The disclosed cooling unit will solve the problem of returning to an overheated vehicle at the end of the day spent in a parking lot, unshielded from the sun and heat. The unit's ability to passively cool a vehicle will prove to be an asset during summers, providing comfort and efficiency to the consumer. Additional uses for this unit are extensive due to its portability. Small aircraft, tents, cabins, park shelters, buildings, and other structures that may lack of access to a power source could also be cooled by the disclosed unit.

The disclosed portable solar powered cooling unit is distinct from existing units, for example those disclosed in U.S. Pat. Nos. 5,826,435 and 4,658,599, U.S. Patent Application No. 20140223945 and Chinese Patent No. 103743011, because of at least its portability. In prior units, integration into a vehicle is disclosed or required, which is not required in the design of the disclosed portable solar powered cooling unit. Cooling coils and compression for true air conditioning are disclosed or required in prior units, but are not required to be included in the disclosed portable solar powered cooling unit. Instead, high efficiency thermoelectric units may be utilized in the disclosed portable solar powered cooling unit. A minimal and purely electrical/mechanical regulation of power and temperature via analog input included in the disclosed portable solar powered cooling unit distinguishes it from units with a complex thermostat, making the disclosed portable solar powered cooling unit more robust and resistant to conditions while also decreasing or eliminating the possibility of software/firmware failure. The use of a rechargeable battery as included in the disclosed portable solar powered cooling unit also distinguishes it from prior units.

### BRIEF DESCRIPTION OF THE DRAWINGS

Various embodiments of the invention are described herein in by way of example in conjunction with the following figures, wherein like reference characters designate the same or similar elements.

FIG. 1 shows a sagittal cut of one embodiment of the disclosed cooling unit.

FIG. 2 depicts a detailed view of one embodiment of a cooling unit, including the heat sinks, peltier unit, form factor, and fan.

FIG. 3 depicts for one preferred embodiment, a logical flow of power in a cooling unit.

FIG. 4 depicts another preferred embodiment of the flow of power in a cooling unit.

FIG. 5 depicts another embodiment of a cooling unit.

FIG. 6 depicts one embodiment of a cooling unit with a solar panel and hoses.

FIG. 7 depicts the top view of one embodiment of a cooling unit.

### DETAILED DESCRIPTION

It is to be understood that at least some of the figures and descriptions of the invention have been simplified to illustrate elements that are relevant for a clear understanding of the invention, while eliminating, for purposes of clarity, other elements that those of ordinary skill in the art will appreciate may also comprise a portion of the invention. However, because such elements are well known in the art, and because they do not facilitate a better understanding of the invention, a description of such elements is not provided herein.

In one embodiment of the disclosed invention, a portable air cooling unit comprises: a power supply that will be rechargeable via solar panels and provide power for the unit's individual components, a unit which will allocate power to the fan and thermoelectric unit, a heat sink to dissipate excess heat generated by the thermoelectric unit, a cooling sink/channel/unit that will dissipate the cold generated by the thermoelectric unit via conduction, a form factor that will allow air to be cooled by the thermoelectric unit, and dissipated via air flow.

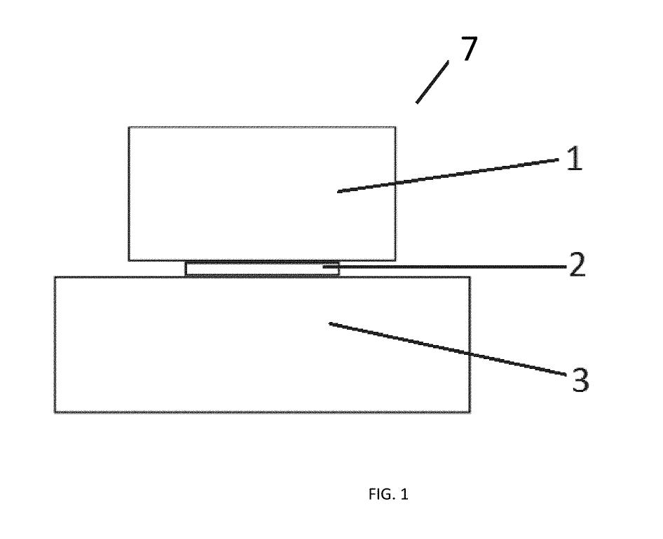

In an embodiment of a cooling unit 7 depicted in FIG. 1, a metal alloy heat sink 1 is operably connected to a Peltier or Thermoelectric unit 2. The unit 2 is operably connected to another metal alloy heat sink 3. This Thermoelectric unit 2 is thus in contact on one side with heat sink 1 and on another side with heat sink 3, to dissipate the cold and heat, respectively, generated by unit 2. The heat sink 3 is a metal alloy heat sink, likely to be larger than heat sink 1. This is to accommodate the fact that the Peltier unit 2 generates much more heat than cold. In this embodiment, ambient air is blown through a passage leading to the heat sink 1 and is cooled in passing. This air is dispersed into the desired area to be cooled. In this embodiment, ambient air is blown through a passage leading to the heat sink 3, and is heated in passing. This heated air is dispersed outside of the designated area to be cooled thereby exhausting the byproduct heat.

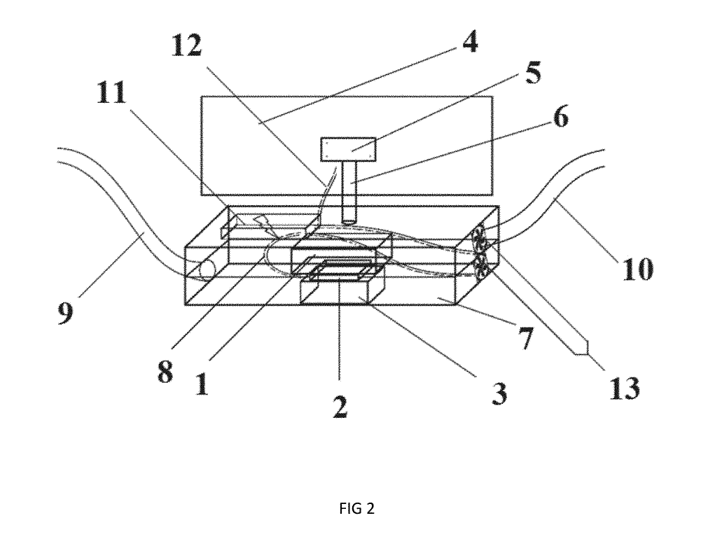

FIG. 2 depicts another preferred embodiment of a cooling unit 7, including the heat sinks 1, 3, thermoelectric unit 2, a form factor comprising ducts 15, 16, and fans 13. A temperature control unit (not depicted), or thermistor, can also be included as part of the cooling unit 7. Solar panel 4, which is used for the generation of power, is wired to power bank 11 via wiring 12. The solar panel 4 can in one embodiment be an ECEEN Solar Panel 15 W or the equivalent. Wiring 12 may be removed and replaced with wiring that permit a longer reach, allowing the user to move the solar panel 4 into a more distant, optimal location. The solar panel 4 may utilize a common plug such as USB or other known and proven connector to ensure safety and reliability. Solar panel 4 is affixed to the cooling unit 7 in this embodiment by mounting point 5, and upright stand 6. Power bank 11 is affixed to the inside of the cooling unit 7. The power bank 11 in one embodiment may be a Monoprice 20,000 mAh power bank or the equivalent. Power bank 11 powers fans 13 by wiring 8. Power bank 11 also powers Thermoelectric unit 2, which simultaneously heats heat sink 1, and cools cold sink 3.

In one embodiment, the Thermoelectric unit 2 may be a SODIAL DC 5V Thermoelectric Cooler or the equivalent, the heat sink 1 may be an a ARCTIC Alpine 64 Pro Rev. 2 or the equivalent, and the cold sink 3 may be a DELL Athalon II CPU Heat sink or the equivalent. The cooling unit 7 houses both a hot duct 15 and a cold duct 16. More specifically, heat sink 1 is contained within a hot duct 15 and heat sink 3 is contained within a cold duct 16. Said ducks 15 and 16 combined can constitute a form factor. One of two fans 13 inducts air into the cold duct 16, passing through cold sink 3, and leading to hose 9 which dissipates cooled air into the desired area to be cooled. One of two fans 13 draws air through the hot duct 15, passing through heat sink 1 and exhausts through hose 10 outside of the area that is being cooled. A physical barrier 9 can be located within the cooling unit 7 to separate it into a hot duct 15 and a cold duct 16. Said physical barrier 9, hot duct 15 and cold duct together can constitute a form factor.

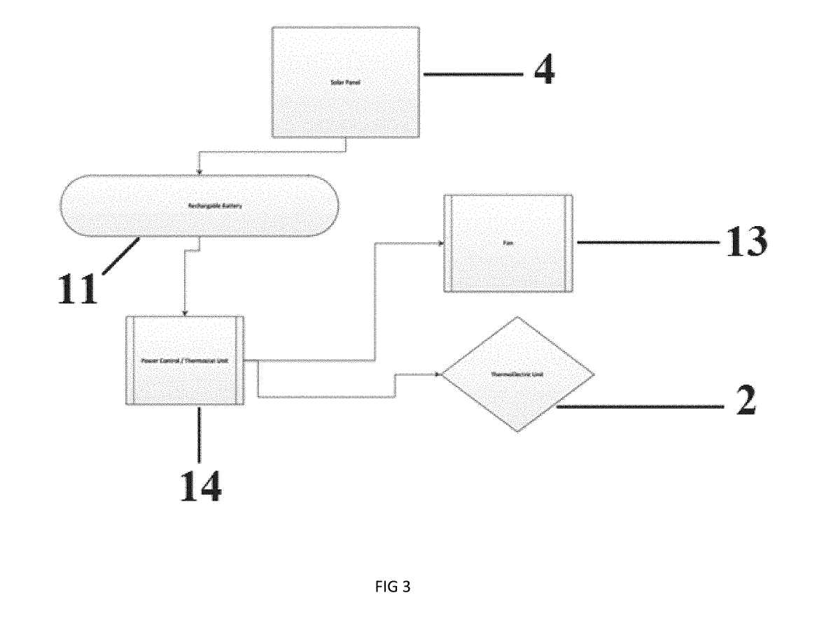

FIG. 3 depicts, for one preferred embodiment, a logical flow of power, from a solar panel 4 or solar panels to a power bank 11, which in one embodiment is a rechargeable battery, and then to a power control 14, which may be a thermostat in one embodiment, which may allocate power to both the fan 13 and thermoelectric unit 2. The connections between these units will be purely electrical/mechanical in nature, dictated by capacitors, potentiometers, and electrical control mechanisms to ensure absolute safety of the device. Series and parallel wiring in the diagram are representative and either series, parallel or a combination of both wiring may be utilized. The power bank 11 or rechargeable battery acts as the central power supply. Solar panels 4 will charge and accordingly be wired to the power bank 11. Likewise, the Peltier unit 2 will be powered by and wired accordingly to said power bank 11. The fans designed to pass air through heat sinks 1 and 3 will be powered by the power bank 11, and wired accordingly. Power may be generated by a solar panel 4, affixed to the invention, or extendable to a more efficient position away from the enclosure—to be exposed to optimal sunlight. The solar panel 4 will charge a rechargeable battery 11. This rechargeable battery 11 may pass power to a power control unit 14 or thermostat unit which will regulate the flow of power relative to the ambient temperature. For instance, the invention will not pass the greatest amount of power possible if a cool temperature is achieved. This power is passed either directly from the rechargeable battery 11 or through the temperature control unit 14 to the fans 13 and thermoelectric unit 2.

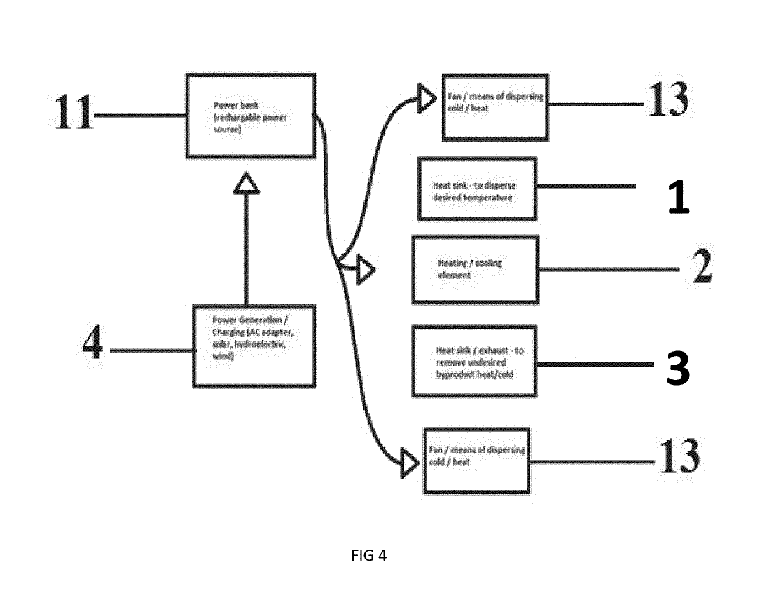

FIG. 4 depicts another preferred embodiment of the flow of power. Series and parallel wiring in the diagram are representative and either series, parallel or a combination of both wiring may be utilized. Power generation occurs from a power generation unit 4 such as solar panels or other means, including without limitation AC, wind, hydroelectric, or solar power generation units or systems. The power generated by power generation unit 4 will charge power bank 11. Power bank 11 acts as the power supply for the fans or other means of dispersing cold/heat 13, and the heating/cooling element 2. The heating/cooling element 2 may be in contact with two heat sinks 1, 2 as also shown in FIG. 4.

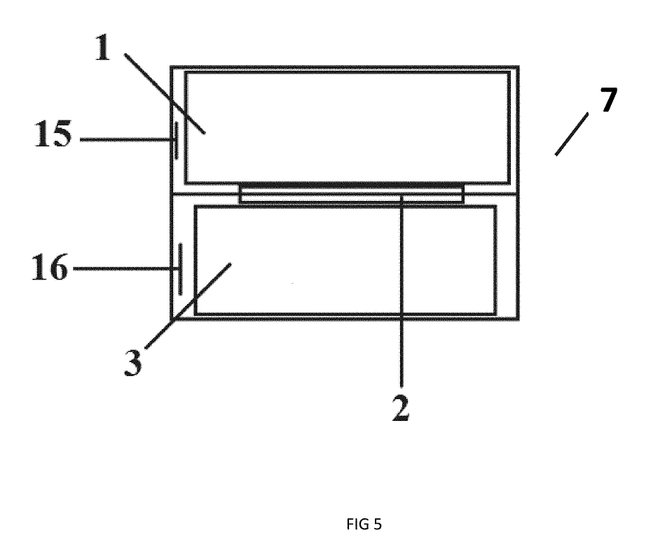

FIG. 5 depicts one view of one preferred embodiment of the cooling unit 7. Thermoelectric unit 2 heats heat sink 1 and heat sink 3. The lower heat sink 3 dissipates channeled, cooled air and the top heat sink 1 aids with dissipation of heat from the unit. As a result, hot duct 15 is a duct containing hot air, and cold duct 16 contains cooled air. A physical barrier 9 separates the hot duct 15 and the cold duct 16.

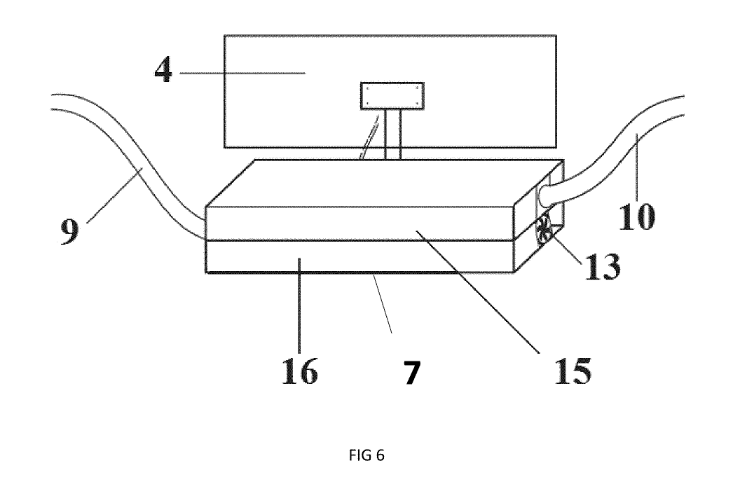

FIG. 6 depicts one embodiment of the cooling unit 7. Solar panel 4 provides power to the power bank (not visible in this figure). Fan 13 inducts air into the cold duct 16, extended by hose 9, which may be directed to the area which is desired to receive cooled air. Hose 10 is the exhaust for the hot duct 15, which will draw heat away from the device, and may be extended outside of the immediate proximity in an ideal configuration. Hoses 9, 10 can also be replaced with ducts or piping and may be flexible or rigid.

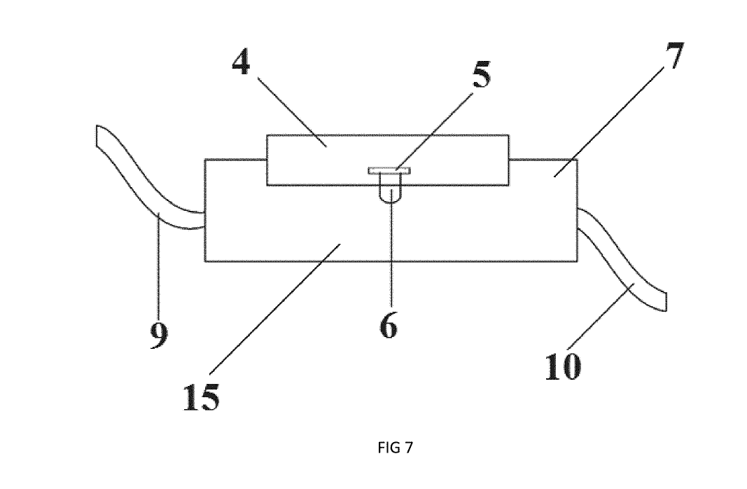

FIG. 7 depicts one embodiment of the invention, from an overhead view. Solar panel 4 is connected to the main cooling unit 7 by a fixture 5, and an upright stand 6. Hose 9 extends the cold duct 16 (not visible in this figure), and may disperse cooled air into the desired area. Hose 10 extends the hot duct 15, and is may exhaust heat outside of the area desired to receive cooling. Hoses 9, 10 can also be replaced with ducts or piping and may be flexible or rigid.

Another preferred embodiment of a cooling unit comprises: A portable cooling unit composed of: a plurality of solar panels; a rechargeable power source; a thermostat unit; a thermoelectric cooling unit; a heat dissipation unit; a cooling unit configured to function as a heat sink; an air distribution device; and a structure that directs air intake and outflow. Further embodiments of a cooling unit comprise: a power source; a heat exchanger; a heat sink; a cold sink; a form factor configured to dissipate cooled air and exhaust heat.

Other embodiments of the disclosed cooling units may include additional features as set forth herein. The units can be coupled to a blower fan which can be used to circulate air through the unit. The units can be downgraded to 5V from a typical 12V configuration or greater. The units can operate without a 12V to 5V stepdown. An NTC unit, such as a thermistor, can be integrated into the circuit to act as analog thermostat unit. The form factor which comprises the hot and cold ducts, can be rectangular, and by design the intake can be smaller, allowing future addition of an air filter. A fan can be seated at the back of the unit, to push air through a cooled (heat) sink to help prevent condensation from forming on the fan and causing damage. Some containment of heat can be accomplished on the heated side of the Peltier unit/heat sink, via retrofitted silicon.

Additional improvements can be incorporated into the units including through the use of heat mapping and the development of more efficient form factors or hot and cold ducts. The materials used and the composition of heat sinks, heat containment, and ductwork can be varied to effect and change effectiveness and durability. The efficiency ratings for either 12V or 5V configurations for both fan and Peltier units in regards to longevity, durability, and runtime/recharge time can be varied. Alternatives to the thermoelectric Peltier units can be utilized to produce endothermic reactions catalyzed by electricity. Improvements to the heat containment of the units can be effected by the recycling of some hot air from the heated side of Peltier unit. A thermostat can also be incorporated into the units, for example, a NTC-103 thermistor, and the placement of the thermostat can be varied. The unit can also incorporate panel charging of the solar bank and overcharge resistance. Optimization of the circuit, voltage regulation, resistance and capacitance for efficiency and durability, including for example, alternative current routes upon failure can also be incorporated into the units. The unit scan also include a 12V or 5V common chargers or adapters for cars, wall outlets, or other power sources.

The unit itself although portable, may be fixed in place for more permanent applications. The unit can be used to provide temperature and humidity control.

The above description of the disclosed embodiments is provided to enable any person skilled in the art to make or use the invention. Various modifications to these embodiments will be readily apparent to those skilled in the art, and the generic principles described herein can be applied to other embodiments without departing from the spirit or scope of the invention. Thus, it is to be understood that the description and drawings presented herein represent a presently preferred embodiment of the invention and are therefore representative of the subject matter which is broadly contemplated by the present invention. It is further understood that the scope of the present invention fully encompasses other embodiments that may become obvious to those skilled in the art and that the scope of the present invention is accordingly limited by nothing other than the appended claims.

What is claimed is:

1. A portable cooling unit comprising:
(a) a solar panel;
(b) a thermoelectric unit powered by said solar panel, said thermoelectric unit having a first side that reduces heat and a second side that generates heat, wherein said first side is in contact with a first heat sink and said second side is in contact with a second heat sink;
(c) said first heat sink configured to cool air in contact with said first heat sink;
(d) said second heat sink configured to heat air in contact with said second heat sink; and
(e) a structure that directs air intake and outflow around said first heat sink and said second heat sink.

2. The portable cooling unit of claim 1, further comprising an air distribution device.

3. The portable cooling unit of claim 2, wherein said air distribution device is a low power high volume fan for distributing air around and in contact with said first heat sink and said second heat sink.

4. The portable cooling unit of claim 1, further comprising a thermostat unit configured to control said cooling unit.

5. The portable cooling unit of claim 4, wherein said thermostat unit is a thermistor.

6. The portable cooling unit of claim 1, wherein said unit is configured to maintain a stable ambient air temperature in a confined space operably connected to said unit via one or more of the following: heating, cooling, or humidity control.

7. The portable cooling unit of claim 1, wherein said structure for directing air intake and outflow comprises a first duct in which said first heat sink is positioned and a second duct in which said second heat sink is positioned.

8. The portable cooling unit of claim 7, wherein a first conduit is operably connected to said first duct to supply cooled air to a confined space and a second conduit is operably connected to said second duct to exhaust heated air away from said confined space and said cooling unit.

9. The portable cooling unit of claim 8, wherein a first fan is operably connected to said first duct to drive air past said first heat sink thereby cooling said air and through said first conduit into a confined space and a second fan is operably connected to said second duct and said second conduit to drive air heated by said second heat sink from said second duct to a location away from said cooling unit.

10. A portable cooling unit comprising:
a power source;
a heat exchanger;
a heat sink;
a cold sink; and
a form factor configured to dissipate air cooled by said cold sink and exhaust air heated by said heat sink.

11. The cooling unit of claim 10, wherein said heat exchanger comprises a Peltier unit.

12. The cooling unit of claim 10 wherein said form factor comprises a first duct in which said heat sink is positioned and a second duct in which said cold sink is positioned.

13. The cooling unit of claim 12 wherein a fan is positioned in operable contact with said second duct to circulate said air cooled by said cold sink.

14. The cooling unit of claim 10, wherein said power source is a solar panel.

15. A method of controlling the temperature in a confined space comprising:
providing a portable cooling unit comprising a power source, a heat exchanger, a heat sink, and a form factor;
providing a source of air to said cooling unit;
venting air cooled by said cooling unit into said confined space; and
exhausting heat to a location outside of said confined space.

16. The method of claim 15, wherein said form factor comprises a duct in which said heat sink is positioned and through which air is passed to cool said air to be vented into said confined space.

17. The method of claim 15, wherein said heat exchanger comprises a Peltier unit.

18. The method of claim 15, wherein said cooling unit further comprises a second heat sink configured to dissipate heat generated by said heat exchanger.

19. The method of claim 15, wherein the operation of said cooling unit is controlled by a thermostat unit.

20. The method of claim 15, wherein said power source comprises a solar panel.
